(19) United States
(12) Patent Application Publication
(10) Pub. No.: US 2026/0247632 A1
(43) Pub. Date: Aug. 20, 2026

(54) MEMORY DEVICE AND MANUFACTURING METHOD THEREOF, AND MEMORY SYSTEM

(71) Applicant: Yangtze Memory Technologies Co., Ltd., Wuhan (CN)

(72) Inventors: Xuening JIA, Wuhan (CN); Zhichao DU, Wuhan (CN); Xu HOU, Wuhan (CN); Shouchun PENG, Wuhan (CN)

(21) Appl. No.: 19/372,429

(22) Filed: Oct. 29, 2025

(30) Foreign Application Priority Data
Feb. 18, 2025 (CN) 202510180435.7

(51) Int. Cl. H10B 80/00; G11C 11/4091; H10B 12/00; H10W 90/00; H10W 80/00

(52) U.S. Cl. CPC H10B 80/00; G11C 11/4091; H10B 12/50; H10W 90/00; H10W 80/312; H10W 80/327; H10W 90/792

(57) ABSTRACT

Examples of the present disclosure provide a memory device and a manufacturing method thereof, and a memory system. The memory device includes: a first semiconductor structure including a memory cell array, bit lines and a first interconnect layer, and a second semiconductor structure including a sense amplifier circuit and a second interconnect layer. The bit lines are coupled to the sense amplifier circuit through the first interconnect layer and the second interconnect layer. A first bit line is connected to the sense amplifier circuit through a first wiring, and a second bit line is connected to the sense amplifier circuit through a second wiring. The first wiring includes a first connection wiring and a first compensation wiring, and the second wiring includes a second connection wiring and a second compensation wiring. The first compensation wiring and the second compensation wiring have different wiring areas.

### CROSS-REFERENCE TO RELATED APPLICATIONS

This application claims priority to Chinese Patent Application No. 202510180435.7, filed on February 18, 2025, which is hereby incorporated by reference in its entirety.

### TECHNICAL FIELD

Examples of the present disclosure relate to the field of semiconductor technology, and in particular, to a memory device and a manufacturing method thereof, and a memory system.

### BACKGROUND

A semiconductor device such as dynamic random access memory (DRAM) is one of the most important access components in an electronic system, and generally employs one transistor and one capacitor to constitute a 1T1C structure as one memory cell. Such 1T1C structure allows the dynamic random access memory to have higher integration and lower cost, and has an irreplaceable status in a computer access device. With the rapid development of semiconductor technology, the dynamic random access memory is rapidly developing towards high density and high quality.

### SUMMARY

Examples of the present disclosure provide a memory device and a manufacturing method thereof, and a memory system.

In a first aspect, an example of the present disclosure provides a memory device, which includes: a first semiconductor structure including a memory cell array, bit lines coupled to the memory cell array, and a first interconnect layer; and a second semiconductor structure including a sense amplifier circuit and a second interconnect layer; the bit lines being coupled to the sense amplifier circuit through the first interconnect layer and the second interconnect layer; the sense amplifier circuit being coupled to a first bit line and a second bit line of the bit lines, wherein the second bit line serves as a reference bit line for the first bit line; the first bit line is connected to the sense amplifier circuit through a first wiring, and the second bit line is connected to the same sense amplifier circuit through a second wiring; the first wiring includes a first connection wiring and a first compensation wiring; the second wiring includes a second connection wiring and a second compensation wiring; and the first compensation wiring and the second compensation wiring have different wiring areas.

In some examples, the first connection wiring is disposed in the first interconnect layer and the second interconnect layer, and the second connection wiring is disposed in the first interconnect layer and the second interconnect layer; and the first connection wiring and the second connection wiring have different wiring lengths.

In some examples, the first compensation wiring is disposed in the first interconnect layer, and the second compensation wiring is disposed in the first interconnect layer; and the first compensation wiring and the second compensation wiring have different wiring lengths.

In some examples, a line width of the first compensation wiring is smaller than a line width of the first connection wiring, and a line width of the second compensation wiring is smaller than a line width of the second connection wiring.

In some examples, a wiring length of the first connection wiring is greater than a wiring length of the second connection wiring, and a wiring area of the first compensation wiring is smaller than a wiring area of the second compensation wiring.

In some examples, the sense amplifier circuit includes a first sense amplifier circuit and a second sense amplifier circuit; the first sense amplifier circuit and the second sense amplifier circuit are coupled to different bit lines through a third wiring and a fourth wiring respectively; the third wiring includes a third connection wiring and a third compensation wiring; the fourth wiring includes a fourth connection wiring and a fourth compensation wiring; a wiring length of the third connection wiring is greater than a wiring length of the fourth connection wiring, and a wiring area of the third compensation wiring is smaller than a wiring area of the fourth compensation wiring.

In some examples, the first semiconductor structure further includes a first bonding structure, and the second semiconductor structure further includes a second bonding structure; the first interconnect layer is located between the memory cell array and the first bonding structure; the second interconnect layer is located between the sense amplifier circuit and the second bonding structure; and the first bonding structure is connected to the second bonding structure.

In some examples, the first interconnect layer is coupled to the first bonding structure; the first interconnect layer includes a plurality of array metal layer; the first compensation wiring is disposed in an array metal layer in the plurality of array metal layer closest to the first bonding structure, and the second compensation wiring is disposed in the array metal layer in the plurality of array metal layer closest to the first bonding structure.

In some examples, the first interconnect layer includes a first array metal layer, a second array metal layer, a third array metal layer and a fourth array metal layer; the fourth array metal layer is connected to the first bonding structure, and the first array metal layer is connected to the bit line; the first connection wiring includes a first array wiring disposed in the first array metal layer, a second array wiring disposed in the second array metal layer, a third array wiring disposed in the third array metal layer and a fourth array wiring disposed in the fourth array metal layer; the first array wiring, the second array wiring, the third array wiring and the fourth array wiring have different line widths; the second connection wiring includes a fifth array wiring disposed in the first array metal layer, a sixth array wiring disposed in the second array metal layer, a seventh array wiring disposed in the third array metal layer and an eighth array wiring disposed in the fourth array metal layer; and the fifth array wiring, the sixth array wiring, the seventh array wiring and the eighth array wiring have different line widths.

In some examples, the first compensation wiring is disposed in the fourth array metal layer; the first compensation wiring is connected to the fourth array wiring, and the first compensation wiring is disposed on the periphery of the fourth array wiring; a line width of the first compensation wiring is smaller than a line width of the fourth array wiring; the second compensation wiring is disposed in the fourth array metal layer; the second compensation wiring is connected to the eighth array wiring, and the second compensation wiring is disposed on the periphery of the eighth array wiring; and a line width of the second compensation wiring is smaller than a line width of the eighth array wiring.

In some examples, a view of the fourth array wiring and the eighth array wiring in a plane perpendicular to a stacking direction overlaps with a view of the first bonding structure in the plane perpendicular to the stacking direction; a view of the first compensation wiring and the second compensation wiring in the plane perpendicular to the stacking direction does not overlap with the view of the first bonding structure in the plane perpendicular to the stacking direction; the stacking direction is a stacking direction of the first semiconductor structure and the second semiconductor structure.

In some examples, the bit line is coupled to the sense amplifier circuit through the first interconnect layer, the first bonding structure, the second bonding structure, and the second interconnect layer.

In some examples, the memory device comprises a dynamic random access memory.

In a second aspect, an example of the present disclosure provides a method for manufacturing a memory device, which includes: forming a first semiconductor structure on a first substrate, the first semiconductor structure including a memory cell array, bit lines coupled to the memory cell array, and a first interconnect layer; forming a second semiconductor structure on a second substrate, the second semiconductor structure including a sense amplifier circuit and a second interconnect layer; bonding and connecting the first semiconductor structure and the second semiconductor structure; the bit lines being coupled to the sense amplifier circuit through the first interconnect layer and the second interconnect layer; the sense amplifier circuit being coupled to a first bit line and a second bit line of the bit lines, wherein the second bit line serves as a reference bit line for the first bit line; the first bit line is connected to the sense amplifier circuit through a first wiring, and the second bit line is connected to the same sense amplifier circuit through a second wiring; the first wiring includes a first connection wiring and a first compensation wiring; the second wiring includes a second connection wiring and a second compensation wiring; and the first compensation wiring and the second compensation wiring having different wiring areas.

In some examples, forming the first semiconductor structure on the first substrate includes: forming the first connection wire and the second connection wire in the first interconnect layer; and forming the second semiconductor structure on the second substrate includes: forming the first connection wire and the second connection wire in the second interconnect layer; wherein the first connection wire and the second connection wire have different lengths.

In some examples, forming the first semiconductor structure on the first substrate further includes: forming the first compensation wiring in the first interconnect layer, and forming the second compensation wiring in the first interconnect layer, wherein the first compensation wiring and the second compensation wiring have different wiring lengths.

In some examples, a line width of the first compensation wiring is smaller than a line width of the first connection wiring; and a line width of the second compensation wiring is smaller than a line width of the second connection wiring.

In some examples, a wiring length of the first connection wiring is greater than a wiring length of the second connection wiring, and a wiring area of the first compensation wiring is smaller than a wiring area of the second compensation wiring.

In some examples, the sense amplifier circuit includes a first sense amplifier circuit and a second sense amplifier circuit; the first sense amplifier circuit and the second sense amplifier circuit are coupled to different bit lines through a third wiring and a fourth wiring respectively; the third wiring includes a third connection wiring and a third compensation wiring; the fourth wiring includes a fourth connection wiring and a fourth compensation wiring; a wiring length of the third connection wiring is greater than a wiring length of the fourth connection wiring, and a wiring area of the third compensation wiring is smaller than a wiring area of the fourth compensation wiring.

In some examples, forming the first semiconductor structure on the first substrate includes: forming a first bonding structure on the first interconnect layer; forming the second semiconductor structure on the second substrate includes: forming a second bonding structure on the second interconnect layer; and bonding the first semiconductor structure and the second semiconductor structure includes: bonding the first semiconductor structure and the second semiconductor structure by connecting the first bonding structure to the second bonding structure.

In some examples, forming the first semiconductor structure on the first substrate includes: forming a plurality of array metal layers, the plurality of array metal layers constituting the first interconnect layer; and the first compensation wiring is disposed in an array metal layer in the plurality of array metal layers closest to the first bonding structure, and the second compensation wiring is disposed in the array metal layer in the plurality of array metal layers closest to the first bonding structure.

In some examples, forming the plurality of array metal layers includes: sequentially forming a first array metal layer, a second array metal layer, a third array metal layer, and a fourth array metal layer; the fourth array metal layer is connected to the first bonding structure, and the first array metal layer is connected to the bit line; the first connection wiring includes a first array wiring disposed in the first array metal layer, a second array wiring disposed in the second array metal layer, a third array wiring disposed in the third array metal layer, and a fourth array wiring disposed in the fourth array metal layer; the first array wiring, the second array wiring, the third array wiring, and the fourth array wiring have different line widths; the second connection wiring includes a fifth array wiring disposed in the first array metal layer, a sixth array wiring disposed in the second array metal layer, a seventh array wiring disposed in the third array metal layer, and an eighth array wiring disposed in the fourth array metal layer; and the fifth array wiring, the sixth array wiring, the seventh array wiring, and the eighth array wiring have different line widths.

In some examples, forming the fourth array metal layer includes: forming the fourth array wiring, the first compensation wiring, the eighth array wiring, and the second compensation wiring in the fourth array metal layer; the first compensation wiring is connected

to the fourth array wiring, and the first compensation wiring is disposed on the periphery of the fourth array wiring; a line width of the first compensation wiring is smaller than a line width of the fourth array wiring; the second compensation wiring is connected to the eighth array wiring, and the second compensation wiring is disposed on the periphery of the eighth array wiring; and a line width of the second compensation wiring is smaller than a line width of the eighth array wiring.

In some examples, a view of the fourth array wiring and the eighth array wiring in a plane perpendicular to a stacking direction overlaps with a view of the first bonding structure in the plane perpendicular to the stacking direction; a view of the first compensation wiring and the second compensation wiring in the plane perpendicular to the stacking direction does not overlap with the view of the first bonding structure in the plane perpendicular to the stacking direction; the stacking direction is a stacking direction of the first semiconductor structure and the second semiconductor structure.

In a third aspect, an example of the present disclosure provides a memory system, which includes: the memory device according to any one of the first aspect; and a memory controller coupled to the memory device and configured to control the memory device.

Embodiments of the present disclosure provide a memory device and a manufacturing method thereof, and a memory system. The memory device comprises: a first semiconductor structure including a memory cell array, bit lines coupled to the memory cell array, and a first interconnect layer; and a second semiconductor structure including a sense amplifier circuit and a second interconnect layer; the bit lines being coupled to the sense amplifier circuit through the first interconnect layer and the second interconnect layer; the sense amplifier circuit being coupled to a first bit line and a second bit line of the bit lines, wherein the second bit line serves as a reference bit line for the first bit line; the first bit line is connected to the sense amplifier circuit through a first wiring, and the second bit line is connected to the same sense amplifier circuit through a second wiring; the first wiring includes a first connection wiring and a first compensation wiring; the second wiring includes a second connection wiring and a second compensation wiring; and the first compensation wiring and the second compensation wiring have different wiring areas. In the examples of the present disclosure, a wiring area of a corresponding compensation wiring can be set based on a wiring length of a connection wiring between the bit line and the SA, so that balance of coupling capacitance between adjacent bit lines can be improved to reduce sensing margin loss caused by different coupling capacitances between adjacent bit lines.

### BRIEF DESCRIPTION OF DRAWINGS

FIG. 1 is a schematic diagram of an exemplary system with a memory system according to an example of the present disclosure;

FIG. 2 is a schematic diagram of an exemplary computer system with a memory system according to an example of the present disclosure;

FIG. 3 is a schematic diagram of an exemplary memory device according to an example of the present disclosure;

FIG. 4A is a schematic distribution diagram of a first semiconductor structure and a second semiconductor structure in an exemplary memory device according to an example of the present disclosure;

FIG. 4B is a schematic distribution diagram of a first interconnect layer and a second interconnect layer in an exemplary memory device according to an example of the present disclosure;

FIG. 5 is a schematic distribution top view of a memory cell array and a peripheral circuit in an exemplary memory device according to an example of the present disclosure;

FIG. 6A is a schematic diagram of an arrangement of sense amplifiers in an exemplary memory device according to an example of the present disclosure;

FIG. 6B is a schematic diagram of sensing margin loss of a sense amplifier in an exemplary memory device according to an example of the present disclosure;

FIG. 7A is a first schematic structural diagram of a sense amplifier in an exemplary memory device according to an example of the present disclosure;

FIG. 7B is a second schematic structural diagram of a sense amplifier in an exemplary memory device according to an example of the present disclosure;

FIG. 8 is a schematic wiring diagram of a first wiring DL1 and a second wiring DLb1 in an exemplary memory device according to an example of the present disclosure;

FIG. 9A is a schematic diagram of a bonding structure layout of an SA circuit in an exemplary memory device according to an example of the present disclosure;

FIG. 9B is a schematic diagram of wirings in a fourth array metal layer in an exemplary memory device according to an example of the present disclosure;

FIG. 10 is a schematic flowchart of a manufacturing method of a memory device provided by an example of the present disclosure.

### DETAILED DESCRIPTION

The technical solutions in implementations of the present disclosure will be described below clearly and completely in conjunction with the implementations and the drawings of the present disclosure. Apparently, the implementations described are only part, but not all, of the implementations of the present disclosure. All other implementations obtained by those of ordinary skills in the art based on the implementations in the present disclosure without creative work shall fall within the scope of protection of the present disclosure.

In the following descriptions, a lot of details are given in order to provide the more thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described here, and well-known functions and structures are not described in detail.

In the drawings, the sizes of a layer, a region, and an element and their relative sizes may be exaggerated for clarity. Like reference numerals denote like elements throughout the specification.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although terms first, second, third and the like may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer or part discussed below may be represented as a second element, component, region, layer or part, without departing from the teachings of the present disclosure. However, when the second element, component, region, layer or part is discussed, it does not mean that the first element, component, region, layer or part is necessarily present in the present disclosure.

Spatially relative terms, such as “beneath”, “below”, “lower”, “under”, “over”, “upper”, etc, may be used here for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terms used here are only intended to describe the specific examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

In order to understand the present disclosure thoroughly, detailed operations and detailed structures will be proposed in the following description to set forth the technical solution of the present disclosure. The detailed descriptions of the preferred examples of the present disclosure are as follows. However, the present disclosure may also have other implementations in addition to these detailed descriptions.

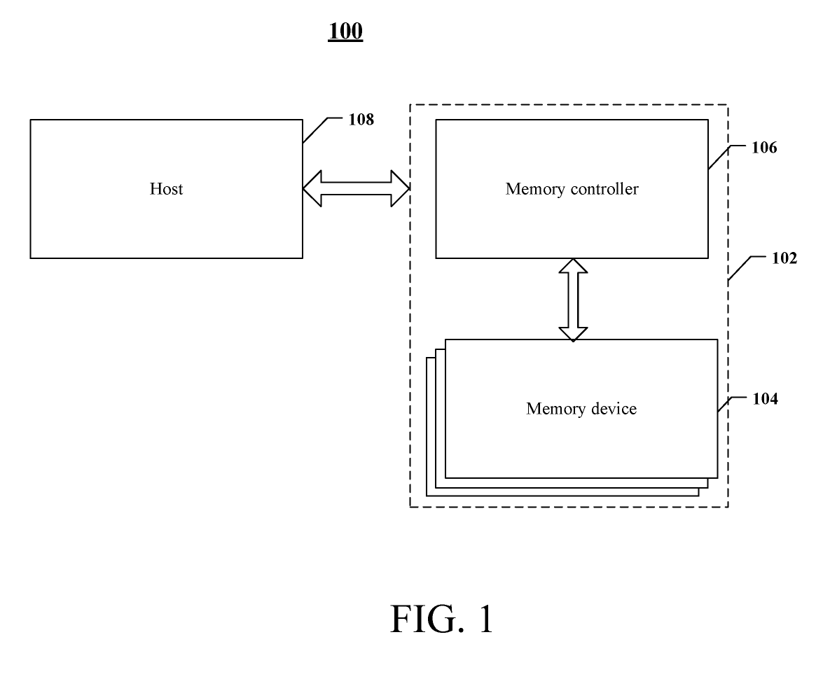

FIG. 1 shows a block diagram of an exemplary system 100 with a memory device according to some aspects of the present disclosure. The system 100 may be a mobile phone, a desktop computer, a laptop computer, a tablet computer, a vehicle computer, a gaming console, a printer, a positioning device, a wearable electronic device, a smart sensor, a virtual reality (VR) device, an augmented reality (AR) device, or any other suitable electronic device with memory therein. As shown in FIG. 1, system 100 may include a host 108 and a memory system 102, which has one or more memory devices 104 and a memory controller 106. The host 108 may be a processor (e.g., a central processing unit (CPU) or a graphics processing unit (GPU)) of an electronic device. The host 108 may be configured to send data to the memory device 104 or to receive data from the memory device 104. The memory controller 106 is coupled to the memory device 104 and the host 108, and is configured to control the memory device 104. The memory controller 106 may manage data stored in memory device 104 and communicate with the host 108.

The memory controller 106 may be configured to control operations of the memory device 104, such as read, erase, write, and refresh operations. In some implementations, the memory controller 106 is further configured to process error correction codes (ECC) with respect to data read from or written to the memory devices 104. The memory controller 106 may also perform any other suitable functions, such as formatting the memory device 104. The memory controller 106 may communicate with an external device (e.g., the host 108) according to a particular communication protocol.

In some specific examples, each of one or more memory devices 104 and the memory controller 106 may be integrated into various types of storage devices. For example, a plurality of memory devices 104 may be integrated into a memory module; and the memory controller 106 may be integrated into a north bridge of a motherboard or directly integrated into a CPU. That is, the memory system 102 may be implemented and packaged into different types of terminal electronic products.

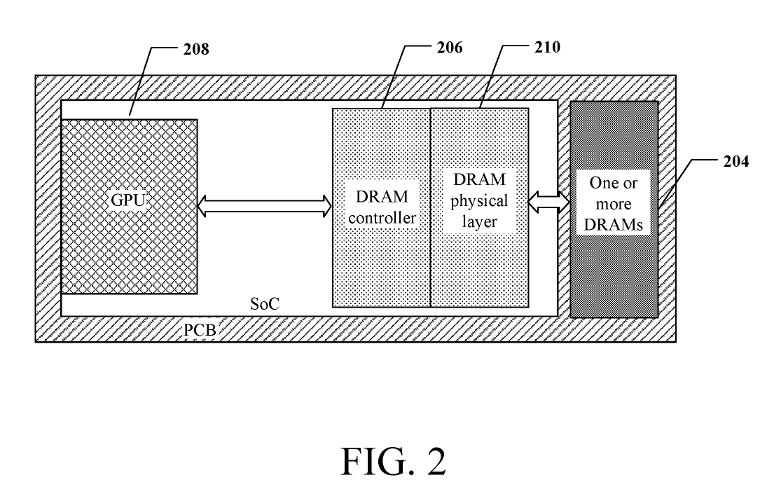

In a system example as shown in FIG. 2, the system includes a system on chip (SoC) and one or more memory devices. The memory device includes a DRAM 204, and the SoC includes a graphics processing unit (GPU) 208, a DRAM controller 206 and a DRAM physical layer 210, wherein the DRAM controller 206 is responsible for scheduling read/write instructions and controlling timing of the DRAM 204, the DRAM physical layer 210 is responsible for completing encoding of the scheduled instructions according to requirements of the DRAM 204, sending corresponding write data to the DRAM 204, and receiving data read from the DRAM 204.

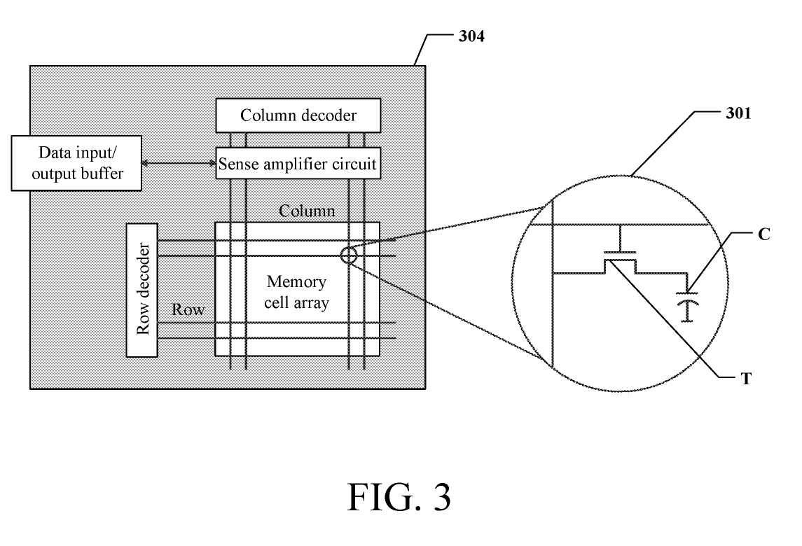

FIG. 3 is a schematic diagram of an exemplary memory device DRAM according to an example of the present disclosure; a circuit of a memory cell in the DRAM is shown on the right side of FIG. 3. Each DRAM chip (die) 304 includes a memory cell array, which includes a plurality of memory cells 301 arranged in an array. Each memory cell 301 includes one transistor T and one capacitor C, and the main function principle of the memory cell is to utilize the amount of charge stored in the capacitor to represent whether one binary bit is 1 or 0. The memory cells are arranged in an array, which can be regarded as a typical mesh structure. The memory array specifies addresses using rows and columns. By specifying the intersection of a row and a column (by specifying the row address and the column address of the DRAM), the memory controller can independently access each memory cell in the DRAM chip and perform an operation of reading or writing the data stored therein.

In some examples, a memory device includes a first semiconductor structure and a second semiconductor structure, wherein the first semiconductor structure includes a memory cell array, and the second semiconductor structure includes a peripheral circuit. The peripheral circuit includes a series of complementary metal-oxide-semiconductor (CMOS) control circuits; for example, the series of CMOS control circuits include: a control circuit corresponding to each memory block, such as a sensing amplifier (SA) and a word-line driver (WLD), etc; a control circuit corresponding to each memory bank, such as a row decoder and a column decoder, etc; and a control circuit corresponding to all memory banks, such as a command buffer, a command decoder, an address buffer, a data buffer, a mode register, etc.

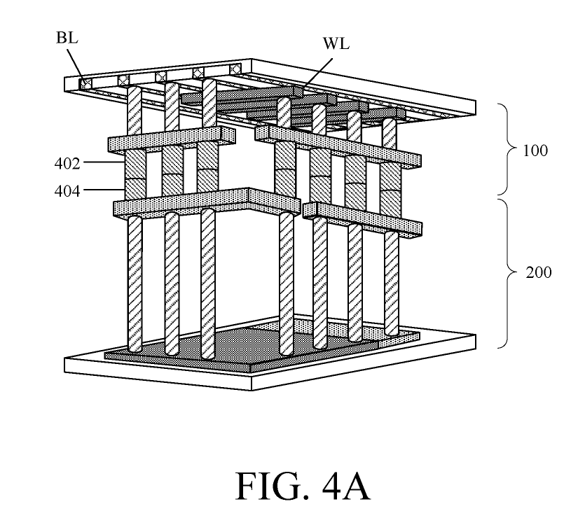

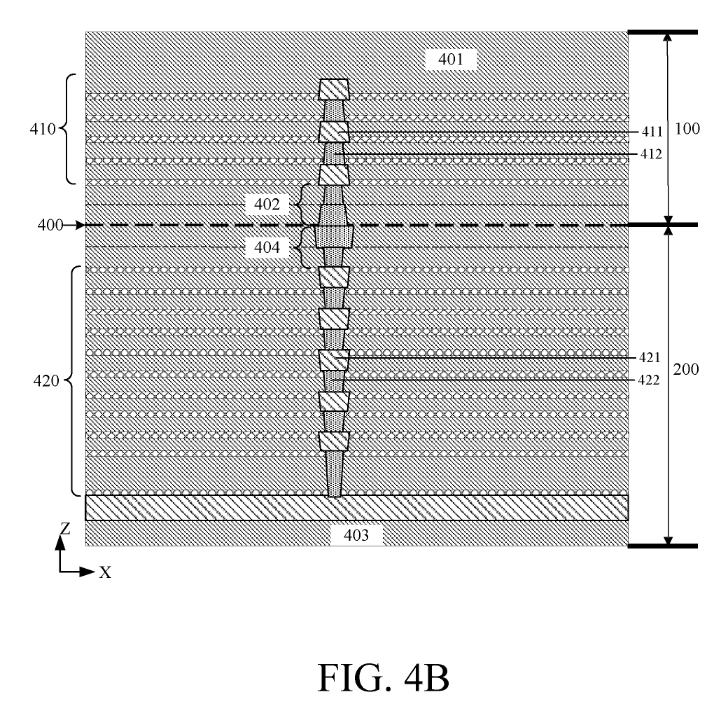

The memory device is described in detail below in conjunction with FIGS. 4A to 6. Before introducing the memory devices shown in FIGS. 4A-6, various directions that may be used in the following description are defined. The stacking direction of the first semiconductor structure and the second semiconductor structure is defined as a vertical direction (i.e., Z direction). X and Y directions intersecting with each other are defined in a plane perpendicular to the Z direction. In some examples, the X direction, the Y direction, and the Z direction may be pairwise perpendicular.

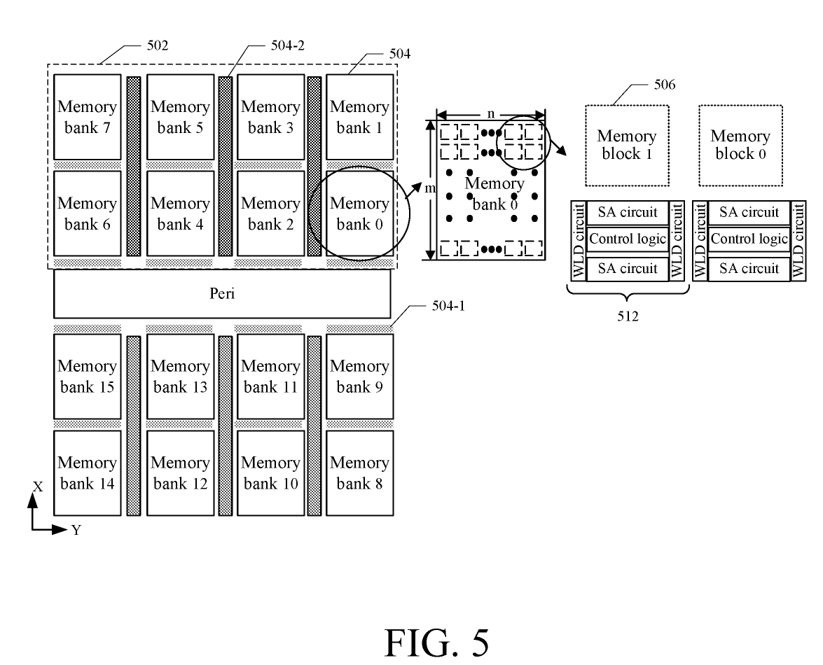

In practical applications, for the layout between the memory cell array and the peripheral circuit, the memory cell array and the peripheral circuit are disposed in parallel on different substrates in some examples. A schematic distribution diagram of a first semiconductor structure and a second semiconductor structure in an exemplary memory device is shown in FIG. 4A; a schematic distribution diagram of a first interconnect layer and a second interconnect layer in an exemplary memory device is shown in FIG. 4B; and a schematic distribution top view of a memory cell array and a peripheral circuit in an exemplary memory device is shown in FIG. 5. As shown in FIGS. 4A and 4B, a first semiconductor structure 100 and a second semiconductor structure 200 are stacked in the vertical direction, and more specifically, a control circuit corresponding to each memory block is disposed on at least one side of that memory block, and a control circuit corresponding to each memory bank is disposed on at least one side of that memory bank.

As shown in FIG. 4A, the memory device includes the first semiconductor structure 100 and the second semiconductor structure 200 coupled to the first semiconductor structure 100. The first semiconductor structure 100 includes a memory cell array, and the second semiconductor structure 200 includes a peripheral circuit. A number of interconnects (e.g., bonding structures) may be formed through a bonding interface 400 to make direct, short distance (e.g., micron scale) electrical connections between the memory cell array and the peripheral circuit. During a back end of line (BEOL) process of the first semiconductor structure 100 including the memory cell array and the second semiconductor structure 200 including the peripheral circuit, interconnects may be formed on the bonding interface to bond two wafers together. In some examples, conductive layers (e.g., metal layers) of word lines and bit lines of the memory cell array may be connected to a WLD circuit, a SA circuit, and other related circuits of the peripheral circuit through interconnects formed on the bonding interface.

FIG. 4A only shows a schematic diagram of bonding connection of the first semiconductor structure 100 and the second semiconductor structure 200 through a first bonding structure 402 and a second bonding structure 404. Word lines and bit lines are shown in the figure by way of example, and for the memory cell array, the specific structure of the peripheral circuit is not limited in FIG. 4A.

In some specific examples, the bonding structures may include a conductive material including, but not limited to, tungsten (W), cobalt (Co), copper (Cu), aluminum (Al), silicide, or any combination thereof. In some specific examples, the first semiconductor structure and the second semiconductor structure are bonded at the bonding interface, and the bonding structures and the surrounding dielectric may be connected by hybrid bonding. That is, in some examples, the bonding interface is formed vertically between the first interconnect layer and the second interconnect layer. In some examples, the memory cell array in the first semiconductor structure and the peripheral circuit in the second semiconductor structure are connected through the first interconnect layer, the first bonding structure, the second bonding structure, and the second interconnect layer. In some examples, the bonding structures may specifically be bonding contacts.

In some examples, the memory cell array and the peripheral circuit are disposed on two substrates. Exemplarily, the memory cell array is formed on a first substrate 401, and the peripheral circuit is formed on a second substrate 403. Here, the first substrate 401 may include, but is not limited to, a silicon substrate. The memory cell array may include a plurality of memory banks, which are arranged in an array. Each memory bank includes a plurality of memory blocks, which are arranged in an array. Each memory block includes a plurality of memory cell rows and a plurality of memory cell columns, each memory cell row and each memory cell column include a plurality of memory cells. The memory cell array 401 may further include a plurality of word lines and a plurality of bit lines, each memory cell row is coupled to a corresponding word line, and each memory cell column is coupled to a corresponding bit line.

Here, the second substrate 403 and the first substrate 401 are different substrates, and the second substrate 403 includes, but is not limited to, a silicon substrate. Hereinafter, the peripheral circuit 402 may include a control circuit corresponding to a memory block and/or a control circuit corresponding to a memory bank. Here, the peripheral circuit 402 further includes control circuits corresponding to all the memory banks, for example, a command buffer, a command decoder, an address buffer, a data buffer, a mode register, etc.

As shown in FIG. 4B, the bonding interface 400 is located between the first semiconductor structure 100 and the second semiconductor structure 200. A first interconnect layer 410 is located between the memory cell array and the bonding interface 400. A second interconnect layer 420 is located between the peripheral circuit and the bonding interface 400. The memory cell array and the peripheral circuit are connected through the first interconnect layer, the first bonding structure, the second bonding structure, and the second interconnect layer. The first interconnect layer and the second interconnect layer may each include a plurality of dielectric layers, a plurality of metal layers, and conductive vias. In some specific examples, the first interconnect layer 410 includes a plurality of array metal layers, for example, the first interconnect layer 410 shown in FIG. 4B includes three array metal layers 411 and conductive vias 412 between adjacent array metal layers 411. The second interconnect layer 420 includes a plurality of peripheral metal layers, for example, the second interconnect layer 420 shown in FIG. 4B includes five peripheral metal layers 421 and conductive vias 422 between adjacent peripheral metal layers 421.

As shown in FIG. 5, the memory device may include one or more memory array structures 502, such as memory dies. Each memory array structure 502 may include a plurality of memory banks 504. For example, as shown in FIG. 5, each memory array structure 502 may include 8 memory banks 504. Each memory bank 504 may include a plurality of memory blocks 506. For example, as shown in FIG. 5, the memory bank 504 may include (n×m) memory blocks 506.

In some examples, a column decoder 504-1 and a row decoder 504-2 corresponding to each memory bank 504 are disposed on both sides of that memory bank 504, and a control circuit 518 is disposed between two memory array structures 502. It should be noted that the number of banks in FIG. 5 is only an example, and is not intended to limit the number of banks in the memory device in the present disclosure.

In some examples, the memory device may further include a plurality of memory block control structures. In some implementations, each memory block control structure may include at least one WLD circuit 514 and at least one SA circuit 516. In some implementations, as shown in FIG. 5, the memory block control structure 512 may include two WLD circuits, two SA circuits, and a control logic. Note that in FIG. 5, the memory block 506 and the memory block control structure 512 are shown side-by-side to account for a size of an area covered by the memory block 506 and the memory block control structure 512. However, in an actual structure, the memory block 506 and the memory block control structure 512 may at least partially overlap with each other in a plan view of the memory device 500. In some implementations, the memory block 506 and the memory block control structure 512 are separately formed on two different wafers or substrates and bonded to each other in at least partially overlapping relationship. In some implementations, the memory block 506 and the memory block control structure 512 may completely overlap with each other.

In some examples, memory block control structures 512 are formed on a first substrate, and one memory block control structure 512 occupies a first region on the first substrate in a plan view of the first substrate. In some implementations, memory blocks 506 are formed on a second substrate, and one memory block 506 occupies a second region on the second substrate in a plan view of the second substrate. After bonding the first substrate with the second substrate, the first region including the WLD circuit and the SA circuit at least partially overlaps with the second region including the memory block 506 in the plan view of the memory device 500. For each memory block 506, two SA circuits oppositely disposed along the X direction and two WLD circuits oppositely disposed along the Y direction are disposed directly below that memory block 506. In some implementations, the first region may include two first sub-regions each having one WLD circuit and two second sub-regions each having one SA circuit. In some examples, the two second sub-regions may be disposed on both sides of the two first sub-regions. In other words, the two SA circuits may be disposed on both sides of the two WLD circuits, as shown in FIG. 5. In some examples, the first region further includes a third sub-region having a control logic, and the third sub-region is located between the two first sub-regions and between the two second sub-regions.

In some examples, when one memory block 506 includes M word lines and N bit lines, each WLD circuit may be configured to control M/2 word lines in a corresponding memory block 506, and each SA circuit may be configured to control N/2 bit lines in a corresponding memory block 506. In some implementations, a SA circuit may be shared by two adjacent memory blocks 506, and one SA circuit may be configured to control odd bit lines or even bit lines in two adjacent memory blocks 506.

It should be noted that size relationship between a size of one memory block and sizes of the SA circuit and the WLD circuit around it shown in FIG. 5 is only an example, and is not intended to limit the size relationship between the size of one memory block and the sizes of the SA circuit and the WLD circuit around it in the memory device of the present disclosure.

It should be noted that the above are only two exemplary layout manners of the memory cell array and the peripheral circuit, and there may be other layouts in practice, and more layout manners will not be repeated here.

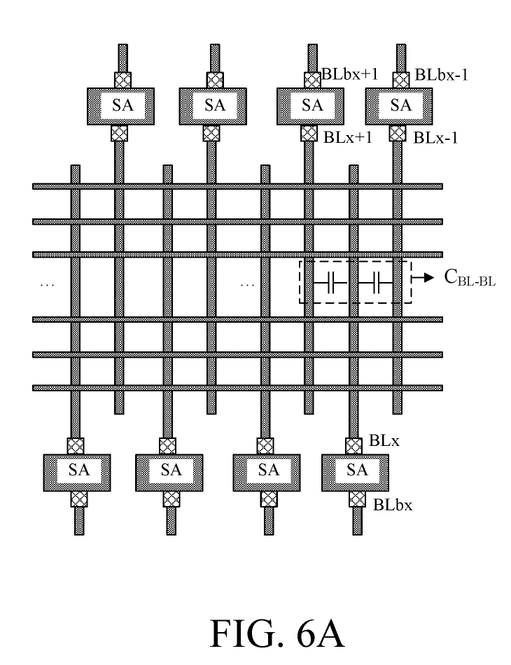

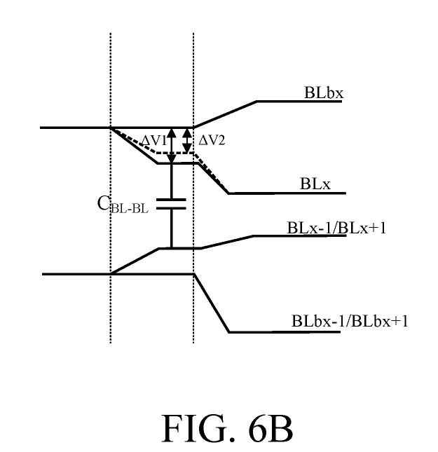

FIG. 6A shows a schematic diagram of an arrangement of sense amplifiers in a memory device according to some aspects of the present disclosure. As shown in FIG. 6A, the SA circuit includes a first SA circuit and a second SA circuit. The first SA circuit may be configured to control even bit lines in the memory block. As shown in FIG. 6A, the first SA circuit includes two outputs, wherein one output is connected to even bit lines in a first memory block, and the other output is connected to even bit lines in a second memory block, and the first memory block and the second memory block are adjacent in the X direction. Similarly, in some implementations, the second SA circuit may be configured to control odd bit lines in the memory block. The second SA circuit includes two outputs, wherein one output is connected to odd bit lines in the second memory block, and the other output is connected to odd bit lines in a third memory block. The second memory block and the third memory block are adjacent in the X direction, and the first memory block is located above the second memory block in the X direction, and the third memory block is located below the second memory block in the X direction, that is, the second memory block is located between the first memory block and the third memory block.

As shown in FIG. 6A, when the SA circuit performs sensing, since there is a coupling capacitance C_{BL-BL} between adjacent bit lines, a sensing signal of a target bit line BLx will be affected by sensing signals of adjacent bit line BLx-1 and adjacent bit line BLx+1, thereby generating sensing margin loss from ΔV1 to ΔV2 as shown in FIG. 6B, where the sensing margin refers to a voltage difference between the target bit line BLx and a reference bit line BLbx during a sensing stage.

Further, as a feature size of a memory is further reduced, a architecture of the memory will be transformed into 4F2, and compared with the 6F2 architecture, a distance between bit lines is closer, and thus a coupling capacitance between adjacent bit lines becomes a main factor affecting sensing margin. The coupling capacitance between adjacent bit lines is unbalanced, which also affects the sensing margin.

In order to improve the balance of the coupling capacitance between adjacent bit lines to reduce the sensing margin loss caused by different coupling capacitances between adjacent bit lines, an example of the present disclosure provides a memory device, which comprises: a first semiconductor structure including a memory cell array, bit lines coupled to the memory cell array, and a first interconnect layer; and a second semiconductor structure including a sense amplifier circuit and a second interconnect layer; the bit lines being coupled to the sense amplifier circuit through the first interconnect layer and the second interconnect layer; the sense amplifier circuit being coupled to a first bit line and a second bit line of bit lines, wherein the second bit line serves as a reference bit line for the first bit line; the first bit line is connected to the sense amplifier circuit via a first wiring, and the second bit line is connected to the same sense amplifier circuit via a second wiring; the first wiring includes a first connection wiring and a first compensation wiring; the second wiring includes a second connection wiring and a second compensation wiring; and the first compensation wiring and the second compensation wiring have different wiring areas.

In some examples, when one memory block includes N bit lines, the SA circuit may be configured to control N/2 bit lines in a corresponding memory block. In some implementations, a SA circuit may be shared by two adjacent memory blocks, and one SA circuit may be configured to control odd bit lines or even bit lines in two adjacent memory blocks. For example, the SA circuit may include two outputs, wherein one output is connected to even bit lines of a memory block, and the other output is connected to even bit lines of a memory block adjacent to the memory block in the Y direction.

In some examples, one SA circuit may include a plurality of sense amplifiers SA, and each SA is shared by two adjacent memory blocks, such as a first memory block and a second memory block. Each SA in the SA circuit may be connected to the first memory block through a first bit line and may be connected to the second memory block through a second bit line, wherein the second bit line serves as a reference bit line for the first bit line. The first bit line is connected to the SA circuit via a first wiring, and the second bit line is connected to the same SA circuit via a second wiring. It should be noted that the first bit line and the second bit line herein are only used to distinguish the bit line connected to the first memory block from the bit line connected to the second memory block, and are not used to limit the order of the bit lines.

In some examples, a plurality of SAs may be alternately arranged on a first side of the memory block and a second side of the memory block opposite to the first side. Each SA arranged on the first side of the memory block may be connected to even bit lines of that memory block, and each SA arranged on the second side of the memory block may be connected to odd bit lines of that memory block. Here, the plurality of SAs arranged on the first side of the memory block may be referred to as a first SA circuit, and the plurality of SAs arranged on the second side of the memory block may be referred to as a second SA circuit.

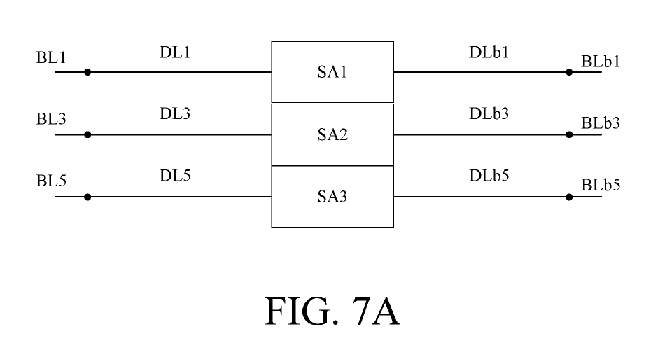

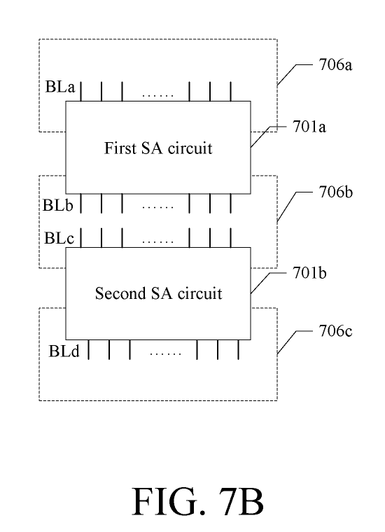

FIG. 7A shows a first schematic structural diagram of a sense amplifier in an exemplary memory device according to an example of the present disclosure. As shown in FIG. 7A, one SA circuit may include a plurality of sense amplifiers SA, each SA is shared by two adjacent memory blocks. FIG. 7A shows three SAs in one SA circuit, which are SA1, SA2, and SA3, respectively.

In some examples, with reference to FIGS. 4B and 7A, the bit line is coupled to the SA circuit via the first interconnect layer, the first bonding structure, the second bonding structure and the second interconnect layer.

As shown in FIG. 7A, the SA1 in the SA circuit is coupled to a first bit line BL1 of a first memory block and a second bit line BLb1 of a second memory block. The second bit line BLb1 serves as a reference bit line for the first bit line BL1. The first bit line BL1 is connected to the SA1 through a first wiring DL1, and the second bit line BLb1 is connected to the same SA1 through a second wiring DLb1. Specifically, one end of the SA1 is connected to the first bit line BL1 through the first wiring DL1, and the other end of the SA1 is connected to the second bit line BLb1 through the second wiring DLb1.

In the examples of the present disclosure, wiring capacitances of the first wiring DL1 and the second wiring DLb1 are equal. It should be noted that wiring capacitances of the first wiring DL1 and the second wiring DLb1 are similar, or a wiring capacitance difference between the first wiring DL1 and the second wiring DLb1 is within a preset range, which is also within the protection scope of the present disclosure. Here, the wiring capacitance of the first wiring DL1 is a parasitic capacitance (or equivalent capacitance) of the first wiring DL1, and the wiring capacitance of the second wiring DLb1 is a parasitic capacitance (or equivalent capacitance) of the second wiring DLb1.

In some examples, a wiring capacitance of a wiring is proportional to a wiring area of the wiring. In other words, the larger the wiring area of the wiring, the larger the wiring capacitance of the wiring.

In some examples, a wiring capacitance of a wiring is proportional to a wiring length of the wiring. In other words, the larger the wiring length of the wiring, the larger the wiring capacitance of the wiring.

FIG. 7A illustrates an example in which a SA circuit is configured to control odd bit lines in two adjacent memory blocks. As shown in FIG. 7A, the SA2 in the SA circuit is coupled to a first bit line BL3 of the first memory block and a second bit line BLb3 of the second memory block. The second bit line BLb3 serves as a reference bit line for the first bit line BL3. The first bit line BL3 is connected to the SA2 through a first wiring DL3, and the second bit line BLb3 is connected to the same SA2 through a second wiring DLb3. The SA3 in the SA circuit is coupled to a first bit line BL5 of the first memory block and a second bit line BLb5 of the second memory block. The second bit line BLb5 serves as a reference bit line for the first bit line BL5. The first bit line BL5 is connected to the SA3 through a first wiring DL5, and the second bit line BLb5 is connected to the same SA3 through a second wiring DLb5.

FIG. 7B shows a second schematic structural diagram of a sense amplifier in an exemplary memory device according to an example of the present disclosure. As shown in FIG. 7B, a first SA circuit 701a may be shared by a first memory block 706a and a second memory block 706b, and the first SA circuit 701a may be configured to control odd bit lines or even bit lines in the first memory block 706a and the second memory block 706b. A second SA circuit 701b may be shared by the second memory block 706b and a third memory block 706c, and the second SA circuit 701b may be configured to control even bit lines or odd bit lines in the second memory block 706b and the third memory block 706c. The first SA circuit 701a includes two outputs, wherein one output is connected to a first bit line BLa, and the other output is connected to a second bit line BLb, the second bit line BLb serves as a reference bit line for the first bit line BLa. The second SA circuit 701b includes two outputs, wherein one output is connected to a first bit line BLc, and the other output is connected to a second bit line BLd, the second bit line BLc serves as a reference bit line for the first bit line BLd. It should be noted that the first bit line and the second bit line herein are only used to distinguish bit lines connected to different memory blocks, and are not used to limit the order of the bit lines.

In some examples, when one memory block includes N bit lines, the second bit line BLb and the first bit line BLc together constitute N bit lines of the second memory block 706b. In other words, the first SA circuit 701a is configured to control N/2 bit lines in the second memory block 706b, and the second SA circuit 701b is configured to control N/2 bit lines in the second memory block 706b. In a specific example, the first SA circuit 701a is configured to control even bit lines in the second memory block 706b, and the second SA circuit 701b is configured to control odd bit lines in the second memory block 706b.

In some examples, the first SA circuit 701a and the second SA circuit 701b are coupled to different bit lines via a third wiring and a fourth wiring, respectively; the third wiring includes a third connection wiring and a third compensation wiring; the fourth wiring includes a fourth connection wiring and a fourth compensation wiring; a wiring length of the third connection wiring is greater than a wiring length of the fourth connection wiring, and a wiring area of the third compensation wiring is smaller than a wiring area of the fourth compensation wiring.

In the examples of the present disclosure, the smaller the wiring distance of the bit line being coupled to the SA is, the larger the wiring area (or wiring length) of the compensation wiring corresponding to the bit line is. Specifically, the smaller the wiring distance of the bit line being coupled to the SA is, the smaller the wiring capacitance of the connection wiring corresponding to the bit line is, and the larger the wiring area (or the wiring length) of the compensation wiring corresponding to the bit line is, the larger the wiring capacitance corresponding to the compensation wiring is, so that the wiring capacitance corresponding to the bit line is more balanced (the wiring capacitances are equal or similar). In other words, the imbalance of the wiring capacitance of the connection wiring can be compensated by the compensation wiring.

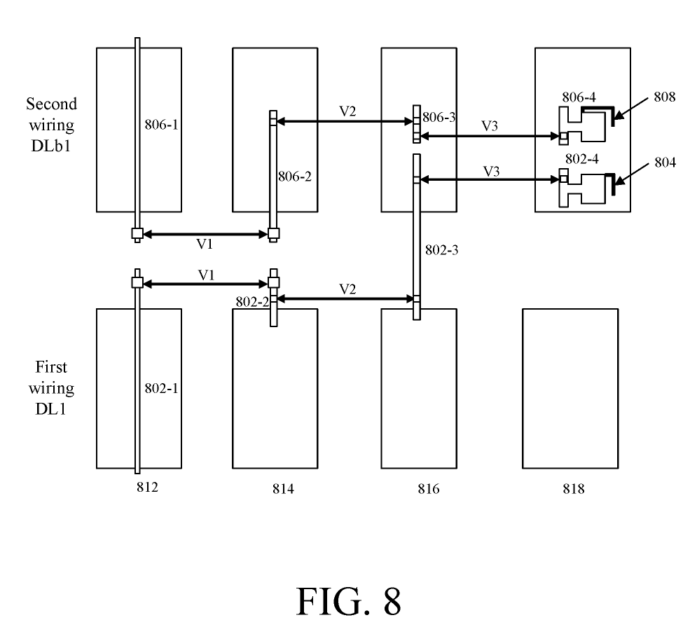

FIG. 8 shows a schematic wiring diagram of a first wiring DL1 and a second wiring DLb1 in an exemplary memory device according to an example of the present disclosure. It should be noted that FIG. 8 only shows a wiring schematic diagram of the first wiring DL1 and the second wiring DLb1 in the first interconnect layer. As shown in FIG. 8, the first wiring DL1 includes a first connection wiring and a first compensation wiring 804; the second wiring DLb1 includes a second connection wiring and a second compensation wiring 808; and the first compensation wiring 804 and the second compensation wiring 808 have different wiring areas.

As shown in FIG. 8, a wiring area of the first wiring DL1 is a sum of a wiring area of the first connection wiring and a wiring area of the first compensation wiring 804. Specifically, the wiring area of the first connection wiring includes an area occupied by a first array wiring 802-1 in a first array metal layer 812, an area occupied by a second array wiring 802-2 in a second array metal layer 814, an area occupied by a third array wiring 802-3 in a third array metal layer 816, and an area occupied by a fourth array wiring 802-4 in a fourth array metal layer 818. The wiring area of the first compensation wiring 804 is an area occupied by the first compensation wiring 804 in the fourth array metal layer 818.

A wiring area of the second wiring DLb1 is a sum of a wiring area of the second connection wiring and a wiring area of the second compensation wiring 808. Specifically, the wiring area of the second connection wiring includes an area occupied by a fifth array wiring 806-1 in the first array metal layer 812, an area occupied by a sixth array wiring 806-2 in the second array metal layer 814, an area occupied by a seventh array wiring 806-3 in the third array metal layer 816, and an area occupied by an eighth array wiring 806-4 in the fourth array metal layer 818. The wiring area of the second compensation wiring 808 is an area occupied by the second compensation wiring 808 in the fourth array metal layer 818.

In some examples, a material of the compensation wiring is the same as a material of the connection wiring. Specifically, materials of the first connection wiring and the first compensation wiring 804 are the same, and materials of the second connection wiring and the second compensation wiring 808 are the same.

In some examples, the first connection wiring is disposed in the first interconnect layer and the second interconnect layer, and the second connection wiring is disposed in the first interconnect layer and the second interconnect layer; and the first connection wiring and the second connection wiring have different wiring lengths.

With reference to FIGS. 7A and 8, wiring lengths of the first connection wirings in the first wirings DL1, DL3 and DL5 are different from wiring lengths of the second connection wirings in the second wirings DLb1, DLb3 and DLb5. In other words, for each SA, its wiring lengths connected to the first bit line and the second bit line are different.

In some examples, as shown in FIG. 8, the first compensation wiring 804 is disposed in the first interconnect layer, and the second compensation wiring 808 is disposed in the first interconnect layer. The first compensation wiring 804 and the second compensation wiring 808 have different wiring lengths.

In some examples, as shown in FIG. 8, a line width of the first compensation wiring 804 is smaller than a line width of the first connection wiring, and a line width of the second compensation wiring 808 is smaller than a line width of the second connection wiring. In a specific example, line widths of the first compensation wiring 804 and the second compensation wiring 808 may be the minimum line width of the wirings in the memory device.

In some examples, as shown in FIG. 8, a wiring length of the first connection wiring is greater than a wiring length of the second connection wiring, and a wiring area of the first compensation wiring 804 is smaller than a wiring area of the second compensation wiring 808. In other words, the smaller the wiring length of the connection wiring in the wiring by which the bit line is coupled to the SA is, the larger the wiring area of the compensation wiring in the wiring by which the bit line is coupled to the SA is.

In some examples, the first semiconductor structure further includes a first bonding structure, and the second semiconductor structure further includes a second bonding structure; the first interconnect layer is located between the memory cell array and the first bonding structure; the second interconnect layer is located between the sense amplifier circuit and the second bonding structure; and the first bonding structure is connected to the second bonding structure. Here, the connection between the first bonding structure and the second bonding structure may be understood with reference to the first bonding structure 402 and the second bonding structure 404 described above and with reference to FIG. 4A and FIG. 4B, and details are not described here again.

In some examples, the first interconnect layer is coupled to the first bonding structure; the first interconnect layer includes a plurality of array metal layers; the first compensation wiring is disposed in an array metal layer in the plurality of array metal layers closest to the first bonding structure, and the second compensation wiring is disposed in the array metal layer in the plurality of array metal layers closest to the first bonding structure. In a specific example, the first interconnect layer sequentially includes three array metal layers: a first array metal layer, a second array metal layer, and a third array metal layer, wherein the first array metal layer is connected to the bit line, the third array metal layer is connected to the first bonding structure, and thus the first compensation wiring and the second compensation wiring are disposed in the third array metal layer.

As shown in FIG. 8, the first interconnect layer may include four array metal layers and conductive channels between every two adjacent array metal layers in the four array metal layers. The conductive channels are configured to provide interconnects in the Z direction. In the Z direction, the first interconnect layer sequentially includes a first array metal layer 812, a conductive channel V1, a second array metal layer 814, a conductive channel V2, a third array metal layer 816, a conductive channel V3, and a fourth array metal layer 818; the fourth array metal layer 818 is connected to the first bonding structure, and the first array metal layer 812 is connected to the bit line.

As shown in FIG. 8, the first connection wiring includes a first array wiring 802-1 disposed in the first array metal layer 812, a second array wiring 802-2 disposed in the second array metal layer 814, a third array wiring 802-3 disposed in the third array metal layer 816, and a fourth array wiring 802-4 disposed in the fourth array metal layer 818; and the first array wiring 802-1, the second array wiring 802-2, the third array wiring 802-3, and the fourth array wiring 802-4 have different line widths. The second connection wiring includes a fifth array wiring 806-1 disposed in the first array metal layer 812, a sixth array wiring 806-2 disposed in the second array metal layer 814, a seventh array wiring 806-3 disposed in the third array metal layer 816, and an eighth array wiring 806-4 disposed in the fourth array metal layer 818; the fifth array wiring 806-1, the sixth array wiring 806-2, the seventh array wiring 806-3, and the eighth array wiring 806-4 have different line widths. In other words, the wirings in each array metal layer in the first interconnect layer have different line widths.

In some examples, the array metal layer in the plurality of array metal layers of the first interconnect layer closest to the first bonding structure is the fourth array metal layer 818, and thus the first compensation wiring 804 and the second compensation wiring 808 are disposed in the fourth array metal layer 818.

In some examples, the relationship between the compensation wiring and the array wiring in the fourth array metal layer 818 is shown in FIG. 8. The first compensation wiring 804 is disposed in the fourth array metal layer 818. The first compensation wiring 804 is connected to the fourth array wiring 802-4, and the first compensation wiring 804 is disposed on the periphery of the fourth array wiring 802-4. A line width of the first compensation wiring 804 is smaller than a line width of the fourth array wiring 802-4. The second compensation wiring 808 is disposed in the fourth array metal layer 818. The second compensation wiring 808 is connected to the eighth array wiring 806-4, and the second compensation wiring 808 is disposed on the periphery of the eighth array wiring 806-4. A line width of the second compensation wiring 808 is smaller than a line width of the eighth array wiring 806-4.

It should be noted that FIG. 8 illustrates an example in which the wiring length of the first connection wiring is greater than the wiring length of the second connection wiring. The first wiring includes the first connection wiring and the first compensation wiring 804, and the first connection wiring includes the fourth array wiring 802-4 disposed in the fourth array metal layer 818. The second wiring includes the second connection wiring and the second compensation wiring 808, and the second connection wiring includes the eighth array wiring 806-4 disposed in the fourth array metal layer 818. The wiring length of the first compensation wiring 804 is smaller than the wiring length of the second compensation wiring 808. Since the line width of the compensation wiring is fixed, the wiring area of the first compensation wiring 804 is smaller than the wiring area of the second compensation wiring 808.

In some examples, a view of the fourth array wiring and the eighth array wiring in a plane perpendicular to the stacking direction overlaps with a view of the first bonding structure in the plane perpendicular to the stacking direction; a view of the first compensation wiring and the second compensation wiring in the plane perpendicular to the stacking direction does not overlap with the view of the first bonding structure in the plane perpendicular to the stacking direction. As shown in FIG. 8, the fourth array wiring 802-4 and the eighth array wiring 806-4 are configured to be coupled to the first bonding structure corresponding to the SA, thus the view of the fourth array wiring and the eighth array wiring in the plane perpendicular to the stacking direction overlaps with the view of the first bonding structure in the plane perpendicular to the stacking direction. The first compensation wiring 804 and the second compensation wiring 808 are only configured to balance the coupling capacitance between adjacent bit lines without increasing the wiring length of the wiring between the bit lines and the SA, so that the view of the first compensation wiring and the second compensation wiring in the plane perpendicular to the stacking direction does not overlap with the view of the first bonding structure in the plane perpendicular to the stacking direction.

In the examples of the present disclosure, the setting of the compensation wiring does not increase the wiring length of the wiring between the bit line and the SA. In other words, the setting of the compensation wiring is not configured to implement the connection and signal transmission between the bit line and the SA, but is configured to balance the coupling capacitance between adjacent bit lines.

In the examples of the present disclosure, the connection wiring is a wiring for actual connection between the bit line and the SA. The compensation wiring is a dummy wiring for compensating a wiring capacitance of a corresponding connection wiring. In other words, the presence or absence of the compensation wiring does not affect the signal transmission between the bit line and the SA.

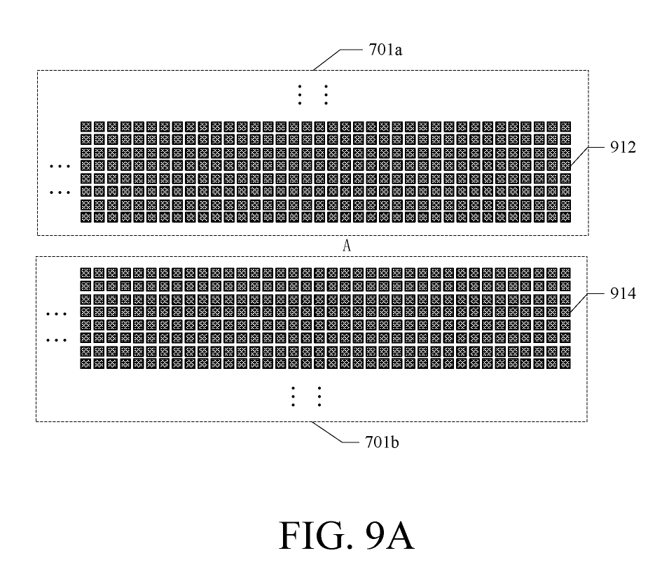

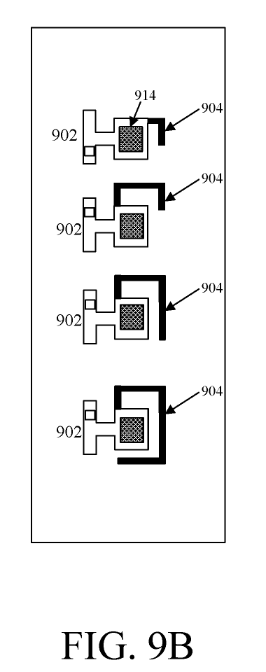

FIG. 9A shows a schematic diagram of a bonding structure layout of an SA circuit in an exemplary memory device according to an example of the present disclosure. With reference to FIG. 7B and FIG. 9A, a bonding structure 912 is a bonding structure corresponding to the first SA circuit 701a, and a bonding structure 914 is a bonding structure corresponding to the second SA circuit 701b. It should be noted that since the first bonding structure and the second bonding structure are correspondingly disposed, the bonding structure shown in FIG. 9A may be the first bonding structure or the second bonding structure.

FIG. 9B shows a schematic diagram of wiring in a fourth array metal layer in an exemplary memory device according to an example of the present disclosure. It should be noted that FIG. 9B illustrates a wiring connection to the second SA circuit 701b as an example. FIG. 9B shows a schematic diagram of a local wiring of the fourth array metal layer. In addition, to clearly show a connection relationship between the wiring of the fourth array metal layer and the first bonding structure corresponding to the SA, FIG. 9B further shows the first bonding structure (914 shown in FIG. 9A). With reference to FIG. 7B, FIG. 9A and FIG. 9B, the fourth array metal layer includes a plurality of connection wirings 902 and a plurality of compensation wirings 904. The connection wirings 902 and the compensation wirings 904 are correspondingly disposed. Each connection wiring 902 is correspondingly connected to a bit line and a first bonding structure 914. The closer the second SA circuit 701b is closer to the memory block, the wiring length of the connection wiring 902 through which the second SA circuit 701b is coupled to the bit line is smaller, and thus the wiring length of the compensation wirings 904 corresponding to the second SA circuit 701b is larger. In contrast, where the second SA circuit 701b is farther away from the memory block, the wiring length of the connection wiring 902 through which the second SA circuit 701b is coupled to the bit line is larger, and thus the wiring length of the compensation wiring 904 corresponding to the second SA circuit 701b is smaller. Since the first bonding structures corresponding to the SA coupled to each bit line are located at different positions (in a view of a plane of the first semiconductor structure), the wiring between each bit line and the SA inevitably has different parasitic capacitances. Therefore, by adding a compensation wiring with a smaller line width near a coupling node between the fourth array metal layer and the first bonding structure, the parasitic capacitance of the wiring can be balanced, thereby balancing the coupling capacitance between adjacent bit lines.

It should be noted that since the SA needs to be connected to two bit lines, the SA also corresponds to two first bonding structures, for example, each SA is correspondingly connected to two bonding contacts. Since positions of the two bonding contacts corresponding to each SA are different, wiring distances of wirings connecting the two bonding contacts to the same SA are also different. In this way, wiring lengths (or wiring areas) of two compensation wirings corresponding to the same SA are also different.

In some examples, the memory device includes a dynamic random access memory.

In some examples, the memory cell array includes a plurality of memory cells, each memory cell includes one vertical transistor and one capacitor.

In a first aspect, in the examples of the present disclosure, a wiring area (or wiring length) of a corresponding compensation wiring is set based on a wiring length of a connection wiring between the bit line and the SA, thereby optimizing a layout between the bit line and the SA, and improving the balance of the coupling capacitance between adjacent bit lines, so as to reduce sensing margin loss caused by different coupling capacitances between adjacent bit lines.

In a second aspect, in the examples of the present disclosure, the compensation wiring is disposed in the first interconnect layer, and a wiring space of the first interconnect layer is larger than that of the second interconnect layer. Further, in the examples of the present disclosure, the compensation wiring is disposed in the array metal layer closest to the first bonding structure, and since the array metal layer closest to the first bonding structure is mainly configured to be connected to the first bonding structure, a wiring space in the array metal layer closest to the first bonding structure is larger, which can improve flexibility of an arrangement of the compensation wiring.

In a third aspect, in the array metal layer closest to the first bonding structure, the compensation wiring is disposed on the periphery of the connection wiring, that is, the compensation wiring is disposed on the periphery of the coupling node between the array metal layer and the first bonding structure, which facilitates reducing a trace occupied by the wiring and reducing a distance and interference between adjacent wirings.

An example of the present disclosure further provides a memory system, which includes: one or more memory devices as described in any of the above examples; and a memory controller coupled to the memory device and configured to control the memory device.

Here, for a specific structure and composition of the memory system, reference may be made to a related structure and composition of the memory system 102 in FIG. 1. For brevity, details are not described here again.

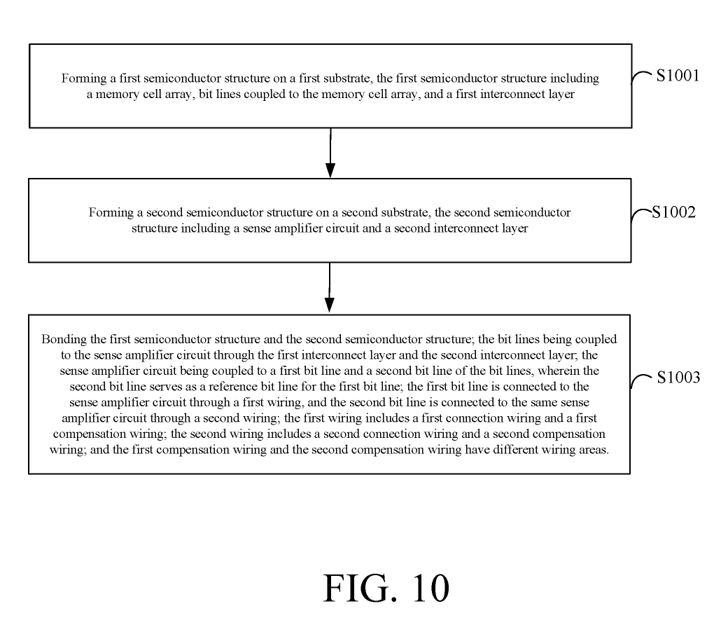

Based on the above memory device, an example of the present disclosure further provides a manufacturing method of a memory device. As shown in FIG. 10, the method comprises:

Operation S1001: forming a first semiconductor structure on a first substrate, the first semiconductor structure including a memory cell array, bit lines coupled to the memory cell array, and a first interconnect layer;

Operation S1002: forming a second semiconductor structure on a second substrate, the second semiconductor structure including a sense amplifier circuit and a second interconnect layer.

Operation S1003: bonding the first semiconductor structure and the second semiconductor structure; the bit lines being coupled to the sense amplifier circuit through a first interconnect layer and a second interconnect layer; the sense amplifier circuit being coupled to a first bit line and a second bit line of the bit lines, wherein the second bit line serves as a reference bit line for the first bit line; the first bit line is connected to the sense amplifier circuit through a first wiring, and the second bit line is connected to the same sense amplifier circuit via a second wiring; the first wiring includes a first connection wiring and a first compensation wiring; the second wiring includes a second connection wiring and a second compensation wiring; and the first compensation wiring and the second compensation wiring have different wiring areas.

In some examples, forming the first semiconductor structure on the first substrate includes: forming a first connection wire and a second connection wire in the first interconnect layer; forming the second semiconductor structure on the second substrate includes: forming the first connection wire and the second connection wire in the second interconnect layer, wherein the first connection wire and the second connection wire have different lengths.

In some examples, forming the first semiconductor structure on the first substrate further includes: forming a first compensation wiring in the first interconnect layer, and forming a second compensation wiring in the first interconnect layer, wherein the first compensation wiring and the second compensation wiring have different wiring lengths.

In some examples, a line width of the first compensation wiring is smaller than a line width of the first connection wiring; and a line width of the second compensation wiring is smaller than a line width of the second connection wiring.

In some examples, a wiring length of the first connection wiring is greater than a wiring length of the second connection wiring, and a wiring area of the first compensation wiring is smaller than a wiring area of the second compensation wiring.

In some examples, the sense amplifier circuit includes a first sense amplifier circuit and a second sense amplifier circuit; the first sense amplifier circuit and the second sense amplifier circuit are coupled to different bit lines through a third wiring and a fourth wiring respectively; the third wiring includes a third connection wiring and a third compensation wiring; the fourth wiring includes a fourth connection wiring and a fourth compensation wiring; a wiring length of the third connection wiring is greater than a wiring length of the fourth connection wiring, and a wiring area of the third compensation wiring is smaller than a wiring area of the fourth compensation wiring.

In some examples, forming the first semiconductor structure on the first substrate includes: forming a first bonding structure on the first interconnect layer; forming the second semiconductor structure on the second substrate includes: forming a second bonding structure on the second interconnect layer; and bonding the first semiconductor structure and the second semiconductor structure includes: bonding the first semiconductor structure and the second semiconductor structure by connecting the first bonding structure to the second bonding structure.

In some examples, forming the first semiconductor structure on the first substrate includes: forming a plurality of array metal layers, the plurality of array metal layers constituting the first interconnect layer; and the first compensation wiring is disposed in an array metal layer in the plurality of array metal layers closest to the first bonding structure, and the second compensation wiring is disposed in the array metal layer in the plurality of array metal layers closest to the first bonding structure.

In some examples, forming the plurality of array metal layers includes: sequentially forming a first array metal layer, a second array metal layer, a third array metal layer, and a fourth array metal layer; the fourth array metal layer is connected to the first bonding structure, and the first array metal layer is connected to the bit line; the first connection wiring includes a first array wiring disposed in the first array metal layer, a second array wiring disposed in the second array metal layer, a third array wiring disposed in the third array metal layer, and a fourth array wiring disposed in the fourth array metal layer; the first array wiring, the second array wiring, the third array wiring, and the fourth array wiring have different line widths; the second connection wiring includes a fifth array wiring disposed in the first array metal layer, a sixth array wiring disposed in the second array metal layer, a seventh array wiring disposed in the third array metal layer, and an eighth array wiring disposed in the fourth array metal layer; and the fifth array wiring, the sixth array wiring, the seventh array wiring, and the eighth array wiring have different line widths.

In some examples, forming the fourth array metal layer includes: forming the fourth array wiring, the first compensation wiring, the eighth array wiring, and the second compensation wiring in the fourth array metal layer; the first compensation wiring is connected to the fourth array wiring, and the first compensation wiring is disposed on the periphery of the fourth array wiring; a line width of the first compensation wiring is smaller than a line width of the fourth array wiring; the second compensation wiring is connected to the eighth array wiring, and the second compensation wiring is disposed on the periphery of the eighth array wiring; and a line width of the second compensation wiring is smaller than a line width of the eighth array wiring.

In some examples, a view of the fourth array wiring and the eighth array wiring in a plane perpendicular to a stacking direction overlaps with a view of the first bonding structure in the plane perpendicular to the stacking direction; a view of the first compensation wiring and the second compensation wiring in the plane perpendicular to the stacking direction does not overlap with a view of the first bonding structure in the plane perpendicular to the stacking direction; the stacking direction is a stacking direction of the first semiconductor structure and the second semiconductor structure.

Here, for the specific structure of the memory device manufactured by the manufacturing method of the memory device, reference is made to examples of the above memory device. Since the manufacturing method of the memory device adopts all the technical solutions of all the examples of the above memory device, it has at least all the beneficial effects brought by the technical solutions of the examples of the above memory device, which will not be repeated here.

It should be understood that “one example” or “an example” mentioned throughout the specification means that specific features, structures, or characteristics related to the example are included in at least one example of the present disclosure. Thus, “in one example” or “in an example” appearing throughout the specification does not necessarily refer to the same example. Further, these specific features, structures, or characteristics may be combined in one or more examples in any suitable manner. It should be understood that, in various examples of the present disclosure, the sequence numbers of the above processes do not mean a order of execution sequences, and an execution sequence of each process should be determined by function and intrinsic logic thereof, and should not constitute any limitation on implementation processes of examples of the present disclosure. The sequence numbers of the above examples of the present disclosure are merely for description, and do not represent the advantages or disadvantages of examples.

The above descriptions are merely preferred implementations of the present disclosure, and not intended to limit the patent scope of the present disclosure. Equivalent structure transformation made by utilizing the contents of the specification and the drawings of the present disclosure under the inventive concept of the present disclosure, or direct/indirect application to other related technical fields are both encompassed within the patent protection scope of the present disclosure.

1. A memory device comprising:
a first semiconductor structure comprising a memory cell array, bit lines coupled to the memory cell array, and a first interconnect layer; and
a second semiconductor structure comprising a sense amplifier circuit and a second interconnect layer, wherein the first interconnect layer and the second interconnect layer are located between the bit lines and the sense amplifier circuit,
wherein the sense amplifier circuit is coupled to a first bit line and a second bit line of the bit lines, and the second bit line serves as a reference bit line for the first bit line,
wherein the first bit line is connected to the sense amplifier circuit through a first wiring, and the second bit line is connected to the sense amplifier circuit through a second wiring, and
wherein the first wiring comprises a first connection wiring and a first compensation wiring, the second wiring comprises a second connection wiring and a second compensation wiring, and the first compensation wiring and the second compensation wiring have different wiring areas.

2. The memory device according to claim 1, wherein the first connection wiring is disposed in the first interconnect layer and the second interconnect layer, the second connection wiring is disposed in the first interconnect layer and the second interconnect layer, and the first connection wiring and the second connection wiring have different wiring lengths.

3. The memory device according to claim 1, wherein the first compensation wiring is disposed in the first interconnect layer, the second compensation wiring is disposed in the first interconnect layer, and the first compensation wiring and the second compensation wiring have different wiring lengths.

4. The memory device according to claim 3, wherein a line width of the first compensation wiring is smaller than a line width of the first connection wiring, and a line width of the second compensation wiring is smaller than a line width of the second connection wiring.

5. The memory device according to claim 1, wherein a wiring length of the first connection wiring is greater than a wiring length of the second connection wiring, and a wiring area of the first compensation wiring is smaller than a wiring area of the second compensation wiring.

6. The memory device according to claim 1, wherein the sense amplifier circuit comprises a first sense amplifier circuit and a second sense amplifier circuit,
wherein the first sense amplifier circuit and the second sense amplifier circuit are coupled to different bit lines through a third wiring and a fourth wiring respectively, the third wiring comprises a third connection wiring and a third compensation wiring, and the fourth wiring comprises a fourth connection wiring and a fourth compensation wiring, and
wherein a wiring length of the third connection wiring is greater than a wiring length of the fourth connection wiring, and a wiring area of the third compensation wiring is smaller than a wiring area of the fourth compensation wiring.

7. The memory device according to claim 1, wherein the first semiconductor structure further comprises a first bonding structure, and the second semiconductor structure further comprises a second bonding structure,
wherein the first interconnect layer is located between the memory cell array and the first bonding structure,
wherein the second interconnect layer is located between the sense amplifier circuit and the second bonding structure; and
wherein the first bonding structure is connected to the second bonding structure.

8. The memory device according to claim 7, wherein the first interconnect layer is coupled to the first bonding structure, and the first interconnect layer comprises a plurality of array metal layers, and
wherein the first compensation wiring is disposed in an array metal layer in the plurality of array metal layers closest to the first bonding structure, and the second compensation wiring is disposed in the array metal layer in the plurality of array metal layers closest to the first bonding structure.

9. The memory device according to claim 8, wherein the first interconnect layer comprises a first array metal layer, a second array metal layer, a third array metal layer and a fourth array metal layer, the fourth array metal layer is connected to the first bonding structure, and the first array metal layer is connected to the bit line,
wherein the first connection wiring comprises a first array wiring disposed in the first array metal layer, a second array wiring disposed in the second array metal layer, a third array wiring disposed in the third array metal layer, and a fourth array wiring disposed in the fourth array metal layer, and the first array wiring, the second array wiring, the third array wiring, and the fourth array wiring have different line widths, and
wherein the second connection wiring comprises a fifth array wiring disposed in the first array metal layer, a sixth array wiring disposed in the second array metal layer, a seventh array wiring disposed in the third array metal layer, and an eighth array wiring disposed in the fourth array metal layer, and the fifth array wiring, the sixth array wiring, the seventh array wiring, and the eighth array wiring have different line widths.

10. The memory device according to claim 9, wherein the first compensation wiring is disposed in the fourth array metal layer, the first compensation wiring is connected to the fourth array wiring, and the first compensation wiring is disposed on the periphery of the fourth array wiring, and wherein a line width of the first compensation wiring is smaller than a line width of the fourth array wiring, and
wherein the second compensation wiring is disposed in the fourth array metal layer, the second compensation wiring is connected to the eighth array wiring, and the second compensation wiring is disposed on the periphery of the eighth array wiring, and wherein a line width of the second compensation wiring is smaller than a line width of the eighth array wiring.

11. The memory device according to claim 10, wherein a view of the fourth array wiring and the eighth array wiring in a plane perpendicular to a stacking direction overlaps with a view of the first bonding structure in the plane perpendicular to the stacking direction,
wherein a view of the first compensation wiring and the second compensation wiring in the plane perpendicular to the stacking direction does not overlap with the view of the first bonding structure in the plane perpendicular to the stacking direction, and
wherein the stacking direction is a stacking direction of the first semiconductor structure and the second semiconductor structure.

12. The memory device according to claim 7, wherein the bit line is coupled to the sense amplifier circuit through the first interconnect layer, the first bonding structure, the second bonding structure, and the second interconnect layer.

13. The memory device according to claim 1, wherein the memory device comprises a dynamic random access memory.

14. A manufacturing method of a memory device, comprising:
forming a first semiconductor structure on a first substrate, the first semiconductor structure comprising a memory cell array, bit lines coupled to the memory cell array, and a first interconnect layer;
forming a second semiconductor structure on a second substrate, the second semiconductor structure comprising a sense amplifier circuit and a second interconnect layer; and
bonding the first semiconductor structure and the second semiconductor structure, the bit lines being coupled to the sense amplifier circuit through the first interconnect layer and the second interconnect layer, the sense amplifier circuit being coupled to a first bit line and a second bit line of the bit lines,
wherein the second bit line serves as a reference bit line for the first bit line, the first bit line is connected to the sense amplifier circuit through a first wiring, and the second bit line is connected to the sense amplifier circuit through a second wiring, and
wherein the first wiring comprises a first connection wiring and a first compensation wiring, the second wiring comprises a second connection wiring and a second compensation wiring, and the first compensation wiring and the second compensation wiring have different wiring areas.

15. The manufacturing method of the memory device according to claim 14, wherein forming the first semiconductor structure on the first substrate comprises:
forming the first connection wiring and the second connection wiring in the first interconnect layer; and
wherein forming the second semiconductor structure on the second substrate, comprises:
forming the first connection wiring and the second connection wiring in the second interconnect layer, wherein the first connection wiring and the second connection wiring have different lengths.

16. The manufacturing method of the memory device according to claim 14, wherein forming the first semiconductor structure on the first substrate further comprises:
forming the first compensation wiring in the first interconnect layer, and
forming the second compensation wiring in the first interconnect layer,
wherein the first compensation wiring and the second compensation wiring have different wiring lengths.

17. The manufacturing method of the memory device according to claim 16, wherein a line width of the first compensation wiring is smaller than a line width of the first connection wiring, and a line width of the second compensation wiring is smaller than a line width of the second connection wiring.

18. The manufacturing method of the memory device according to claim 16, wherein a wiring length of the first connection wiring is greater than a wiring length of the second connection wiring, and a wiring area of the first compensation wiring is smaller than a wiring area of the second compensation wiring.

19. The manufacturing method of the memory device according to claim 14, wherein the sense amplifier circuit comprises a first sense amplifier circuit and a second sense amplifier circuit,
wherein the first sense amplifier circuit and the second sense amplifier circuit are coupled to different bit lines through a third wiring and a fourth wiring respectively, and wherein the third wiring comprises a third connection wiring and a third compensation wiring, and the fourth wiring comprises a fourth connection wiring and a fourth compensation wiring, and
wherein a wiring length of the third connection wiring is greater than a wiring length of the fourth connection wiring, and a wiring area of the third compensation wiring is smaller than a wiring area of the fourth compensation wiring.

20. A memory system comprising:
one or more memory devices, a memory device of the one or more memory devices comprising:
a first semiconductor structure comprising a memory cell array, bit lines coupled to the memory cell array, and a first interconnect layer; and
a second semiconductor structure comprising a sense amplifier circuit and a second interconnect layer, wherein the first interconnect layer and the second interconnect layer are located between the bit lines and the sense amplifier circuit,
wherein the sense amplifier circuit is coupled to a first bit line and a second bit line of the bit lines, and the second bit line serves as a reference bit line for the first bit line, wherein the first bit line is connected to the sense amplifier circuit through a first wiring, and the second bit line is connected to the sense amplifier circuit through a second wiring, wherein the first wiring comprises a first connection wiring and a first compensation wiring, the second wiring comprises a second connection wiring and a second compensation wiring, and the first compensation wiring and the second compensation wiring have different wiring areas; and
a memory controller coupled to the one or more memory devices and configured to control the one or more memory devices.
